(19) United States
(12) Patent Application Publication
(10) Pub. No.: US 2009/0016130 A1
(43) Pub. Date: Jan. 15, 2009

(54) MEMORY DEVICE AND METHOD OF TESTING A MEMORY DEVICE

(76) Inventors: MANFRED MENKE, Wolfratshausen (DE); Roman Mayr, Munchen (DE); Paul Wallner, Prien (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/777,189

(22) Filed: Jul. 12, 2007

(51) Int. Cl. G11C 29/00

(52) U.S. Cl. 365/201

(57) ABSTRACT

In a method of testing a memory device, an output path of the memory device and an input path of the memory device are coupled to each other. A signal is transmitted, controlled by a test pattern, via the output path of the memory device. The signal is received via the input path of the memory device and evaluated.

### BACKGROUND OF THE INVENTION

### Field of the Invention

The present invention generally relates to a system, apparatus, and method for testing a memory device and its internal components by coupling the input and the output of the memory device together.

### BRIEF DESCRIPTION OF THE DRAWINGS

The features of embodiments will become clear from the following description, taking in conjunction with the accompanying drawings. It is to be noted, however, that the accompanying drawings illustrate only typical embodiments and are, therefore, not to be considered limiting of the scope of the invention. It may admit other equally effective embodiments.

FIG. 1 shows a schematic representation of a memory device;

FIG. 2 shows a schematic representation of a memory device;

FIG. 3 shows a schematic representation of a memory device;

FIG. 4 shows a schematic representation of a memory device;

FIG. 5 shows a schematic representation of a memory device;

FIG. 6 shows a schematic representation of a memory device;

FIG. 7 shows a schematic representation of a memory device and a memory tester;

FIG. 8 shows a schematic representation of the memory device;

FIG. 9 shows a schematic representation of the memory device;

FIG. 10 shows a schematic representation of the memory device;

FIG. 11 shows a schematic representation of a system; and

FIG. 12 shows a schematic flow chart of a method of testing a memory device.

### DETAILED DESCRIPTION OF THE PREFERRED EMBODIMENT

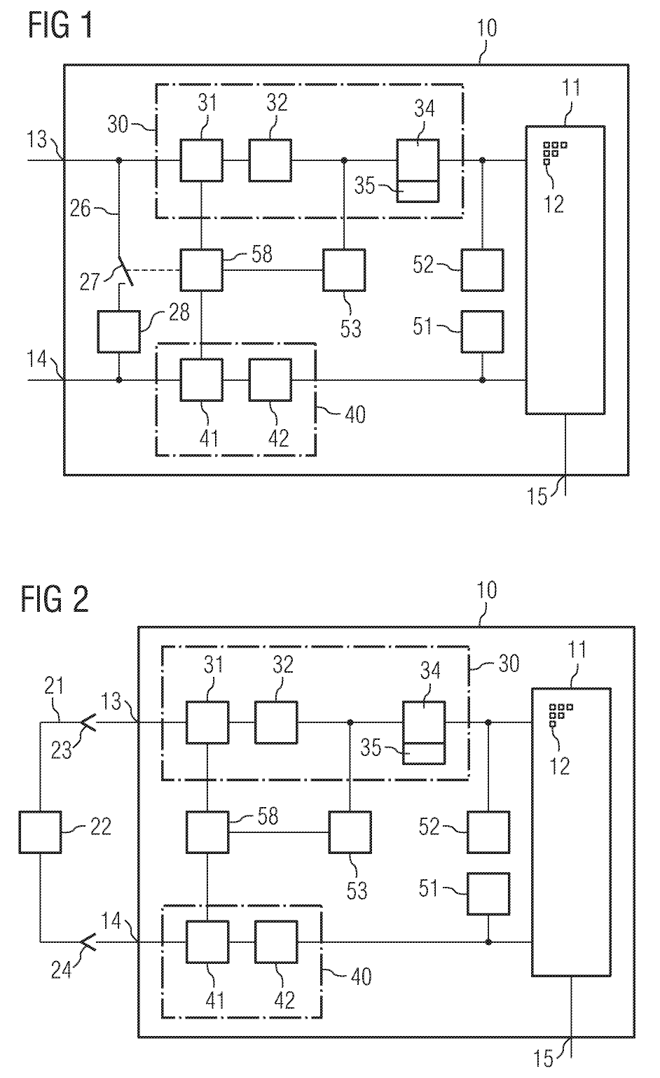

The FIGS. 1 to 5 show schematic representations of various embodiments of memory devices 10. Each of the memory devices 10 described below with reference to the FIGS. 1 to 5 comprises a memory core 11 with a plurality of storage locations 12, an input 13 and an output 14. The memory core 11 can be for example a DRAM, each storage location 12 comprising a storage capacitor and a selection switch. As an alternative, the technology of the memory core 11 and the storage locations 12 is SRAM, MRAM, FRAM, CBRAM, PCRAM, EEPROM, Flash or any other technology for volatile or non-volatile storage of data in more or less localized storage locations 12. At each storage location 12, one or more bits of information can be stored. Each storage location 12 is identified by an address. Information can be written to a storage location 12 identified by an address or read from a storage location 12 identified by an address.

For example, each storage location 12 is a group of memory cells coupled to one of a plurality of word lines. When a word line is identified by an address, the word line is activated and all the memory cells coupled to the word line are coupled to a corresponding number of sense amplifiers or other kinds of read and write amplifiers via a corresponding number of bit lines.

Each of the memory devices 10 described below with reference to FIGS. 1 to 5 can be a chip, or die, (for example a semiconductor chip) comprising the memory core 11 with storage locations 12 and other circuitry described below. In this case, each of the input 13 and the output 14 comprises a number of bond pads or other kinds of contacts that are provided for coupling the memory device 10 to external circuitry. As an alternative or in addition, at least one of input 13 and the output 14 comprises other kinds of electrical contacts or an optical interface for the reception or transmission, respectively, of optical signals.

As an alternative, the memory device 10 comprises one or several semiconductor chips, or dies, (for example semiconductor chips) in a package. In this case, each of the input 13 and the output 14 comprises a number of contacts at one or several outer surfaces of the package. For example, these contacts are small solder contacts arranged in a fine ball grid array (FBGA). Again, at least one of input 13 and the output 14 can, as an alternative or in addition, comprises other kinds of electrical contacts or an optical interface for the reception or transmission, respectively, of optical signals.

As a further alternative, the memory device 10 can be a memory module comprising a printed circuit board and a number of packaged or non-packaged memory devices of any technology (for example DRAM, SRAM, MRAM, FRAM, CBRAM, PCRAM, EEPROM, Flash etc.).

In any case, the input 13 and the output 14 comprise electrical, optical or other interfaces for the reception or transmission, respectively, of signals comprising, or encoding, or representing, data, address or control information.

Each of the memory devices 10 described below with reference to the FIGS. 1 to 5 comprises an input path 30 coupling the input 13 to the memory core 11. The input path 30 comprises an input receiver 31, a de-serializing circuit 32 and a protocol decoder 34 with a posted write buffer 35. An input of the input receiver 31 is coupled to the input 13 of the memory device 10. An output of the input receiver 31 is coupled to an input of the de-serializing circuit 32. An output of the de-serializing circuit 32 is coupled to an input of the protocol decoder 34. An output of the protocol decoder 34 is coupled to an input of the memory core 11. Although the memory devices 10 will be described with reference to these components of the input path 30, many features of the memory devices 10 described below with reference to FIGS. 1 to 5 can also be realized with a different internal structure of the input path 30.

Each of the memory devices 10 described below with reference to the FIGS. 1 to 5 comprises an output path 40 coupling an output of the memory core 11 to the output 14 of the memory device 10. In each of the memory devices 10 described below with reference to the FIGS. 1 to 5, the output path 40 comprises an output driver 41 and a serializing circuit 42. An input of the serializing circuit 42 is coupled to the output of the memory core 11. An output of the serializing circuit 42 is coupled to an input of the output driver 41. An output of the output driver 41 is coupled to the output 14 of the memory device 10. Although the memory devices 10 will be described with reference to these components of the output path 40, further features and aspects of memory devices 10 described below with reference to FIGS. 1 to 5 can also be realized with a different internal structure of the output path 40.

The subsequent description merely refers to one-way communication via each of the input 13, the input path 30, the output 14 and the output path 40. However, each of the input 13, the input path 30, the output 14 and the output path 40 can also be configured for a communication in both directions.

In a normal operating mode, each of the memory devices 10 described below with reference to the FIGS. 1 to 5 receives input signals via the input 13 and transmits output signals via the output 14. The input signals comprise, or encode, or represent, data, address and control information. The signals are received, the information is decoded, processed and forwarded to the memory core 11 by the input path 30.

With the particular components described above, the input receiver 31 receives and amplifies the input signals and, to some extent, decodes the information encoded in the input signals. The de-serializing circuit 32 (at least partly) de-serializes the information. In one embodiment of the memory device 10, the de-serializing circuit 32 comprises a number of signal input lines and a number of signal output lines, wherein the number of signal output lines is larger than the number of signal input lines. For example, the input of the de-serializing circuit 32 is coupled to the output of the input receiver 31 via nᵢ parallel lines, and the output of the de-serializing circuit 32 is coupled to the input of the protocol decoder 34 via nₒ parallel lines, wherein nₒ>nᵢ. In this case, the parallelism is increased by the factor nₒ/nᵢ, and the clock of the output of the de-serializing circuit 32 can be smaller than the clock of the input of the de-serializing circuit 32 by a factor nᵢ/nₒ.

The protocol decoder 34 decodes the protocol of the information encoded in the input signal. For example, in a frame-based protocol, the information is comprised in frames with a predefined length, or size, and/or the beginning and/or the end of each frame is identified by a predefined pattern. Each frame comprises data and/or address information and/or a control command. For example, one frame or several subsequent frames comprise a write comment, an address identifying a storage location 12 or addresses identifying storage locations 12 of the memory core 11, and data to be written to one or more storage locations 12 identified by the addresses, respectively. As a further example, a frame or several subsequent frames comprise a read command, and an address or addresses identifying one or more storage locations 12, respectively, wherefrom data are to be read.

Further control commands can be comprised in the frames. In one embodiment of the memory device 10, the frame can comprise a posting command controlling the writing of control commands and/or data and/or address information to the posted write buffer 35. The information stored in the posted write buffer 35 is then forwarded to the memory core 11 at a later moment in time.

With the above described internal structure of the output path 40, the serializing circuit 42 (at least partly) serializes information received from the memory core 11. For example, the input of the serializing circuit 42 is coupled to the output of the memory core 11 via nᵢ parallel lines, and the output of the serializing circuit 42 is coupled to the input of the output driver 41 via nₒ parallel lines, wherein nᵢ>nₒ. In this case, the serializing circuit 42 reduces parallelism by a factor nₒ/nᵢ, and the clock of the output of the serializing circuit 42 can be larger than the clock of the input of the serializing circuit 42 by a factor nᵢ/nₒ. Signals encoding the frames are generated or amplified by the output driver 41.

Similar to the communication via the input 13 described above, the communication via the output 14 can be in accordance with a frame-based protocol. In this case, the memory core 11 provides frames to the serializing circuit 42, or a protocol encoder not displayed in FIGS. 1 to 5 is provided in the output path 40 between the memory core 11 and the serializing circuit 42.

Referring to FIG. 1, a memory device 10 as described above further comprises a coupling device 26, a coupling switch 27 and an optional degrading device 28 arranged in serial connection between the input 13 and the output 14 of the memory device 10. When the number of signal lines of the input 13 and the number of signal lines of the output 14 are larger than one, the coupling device 26 comprises a corresponding number of signal lines and the coupling switch 27 comprises a corresponding number of single switches. It is to be noted that use of the term “signal lines” may represent one or more individual signal lines. When the coupling switch 27 is closed, the input 13 is coupled to the output 14 of the memory device 10 via the coupling device 26 and the optional degrading device 28. When the coupling switch 27 is open, there is no direct internal coupling of the input 13 and the output 14.

The memory device 10 further comprises a test mode controller 58 coupled to the coupling switch 27 and configured to control the coupling switch 27. As an option, the test mode controller 58 is further coupled to the input receiver 31 and is configured to control the input receiver 31. As a further option, the test mode controller 58 is coupled to and configured to control the output driver 41. When the test mode controller 58 is coupled to the input receiver 31 and/or to the output driver 41, it is configured to control, in a test mode of the memory device 10, one or several parameters of the respective components. These parameters can comprise an amplification gain, a detection threshold, a swing, a phase offset, a voltage offset etc.

In the embodiment schematically represented in FIG. 1, the above described memory device 10 further comprises at least one error detection circuit 51, 52, and/or 53. Although three error detection circuits 51, 52, and 53 are displayed in FIG. 1, the memory device 10 may comprise only one or two of these error detection circuits 51, 52, and/or 53, as an alternative. A first error detection circuit 51 is coupled to the output of the memory core 11, and a second error detection circuit 52 is coupled to the output of the input path 30 and the output of the protocol decoder 34. A third error detection circuit 53 is coupled to the output of the de-serializing circuit 32. Each of the error detection circuits 51, 52, and 53 can be coupled to the test mode controller 58, although in FIG. 1 only the third error detection circuit 53 is coupled to the test mode controller 58.

Each of the error detection circuits 51, 52, and 53 can comprise a multiple input shift register (MISR). Each of the error detection circuits 51, 52, and 53 can also comprise circuitry implementing a pseudo random bit sequence (PRBS) algorithm, for example a feedback shift register. Any of the error detection circuits 51, 52, and 53 can be provided for and configured to detect an error, or failure, of the memory device 10, for example in one of the methods described below.

In a testing mode of the memory device 10, controlled by the test mode controller 58, the coupling switch 27 is closed. Thereby, the input 13, or to be more specific, the input of the input path 30 is coupled to the output 14, or to be more specific, to the output of the output path 40. As a consequence, any signal transmitted via the output path 40 is received via the input path 30. This can be used to test the entire memory device 10 and, the output path 40, and the input path 30. In a testing procedure, a test pattern is read from one or several storage locations 12 of the memory core 11, transmitted via the output path 40, transferred via the degrading device 28, the coupling switch 27 and the coupling device 26 and received via the input path 30. In this testing procedure, one or several of the error detection circuits 51, 52, and 53 can detect errors, or failures, of the memory device 10. Examples for testing procedures will be described below.

FIG. 2 is a schematic representation of another embodiment of a memory device 10. The memory device 10 displayed in FIG. 2 differs from the memory device 10 described above with reference to FIG. 1 in that it does not comprise the coupling device 26, a coupling switch 27 and a degrading device 28. In a testing procedure, the memory device 10 can be coupled to an external coupling device 21. The external coupling device 21 comprises an input connector 23 which can be connected to the input 13 of the memory device 10 and an output connector 24 which can be coupled to the output 14 of the memory device 10. Furthermore, the external coupling device 21 can comprise a degrading device 22. The coupling device 21 with the input connector 23, the output connector 24 and the optional degrading device 22 is not part of the memory device 10. Rather, the coupling device 21 can be part of a testing apparatus for the memory device 10.

Like the memory device 10 described above with reference to FIG. 1, the memory device 10 displayed in FIG. 2 comprises one, two or three error detection circuits 51, 52, and 53. Each of these error detection circuits 51, 52, and 53 can be coupled to the output of the memory core 11, to the output of the input path 30 or to the output of the de-serializing circuit 32 in one of the ways described above with reference to FIG. 1. In a testing procedure, a test pattern stored in the storage locations 12 of the memory core 11 can be transmitted via the output path 40, transferred via the coupling device 21 and received via the input path 30. One or several of the error detection circuits 51, 52, and 53 can detect an error, or failure, of the memory device 10.

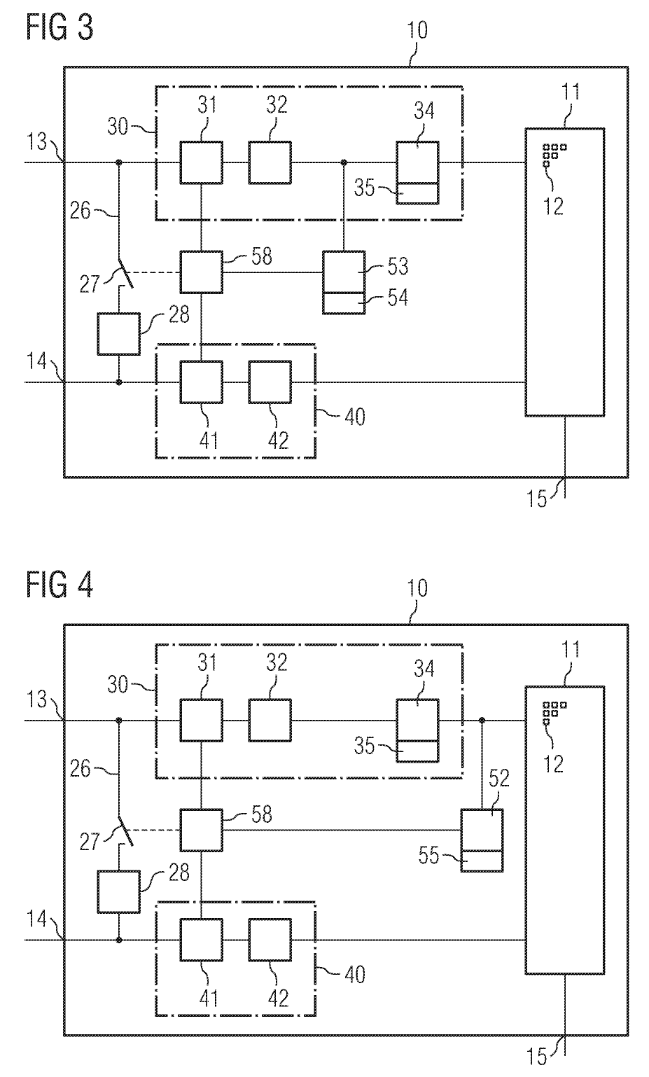

FIG. 3 is a schematic representation of another embodiment of a memory device 10. Like the memory device 10 described above with reference to FIG. 1, the memory device 10 displayed in FIG. 3 comprises a coupling device 26, a coupling switch 27 and a degrading device 28. The coupling device 26, the coupling switch 27 and the degrading device 28 are internal components of the memory device 10. The memory device 10 comprises an error detection circuit 53 with a test pattern generator 54. The test pattern generator 54 is configured to generate a pseudo random pattern or any other predefined test pattern. The error detection circuit 53 can compare the test pattern generated by the test pattern generator 54 with a pattern read from the storage locations 12 of the memory core 11, transmitted via the output path 40, transferred via the degrading device 28, the coupling switch 27 and the coupling device 26, received by the input receiver 31 and de-serialized by the de-serializing circuit 32. When the error detection circuit 53 receives, from the output of the de-serializing circuit 32, a pattern different from the test pattern generated by the test pattern generator 54, at least one of the memory core 11, the output path 40, the input receiver 31 and the de-serializing circuit 32 provides an error, or failure, provided the test pattern generated by the test pattern generator 54 corresponds to the pattern stored in the memory core 11. When the pattern received from the output of de-serializing circuit 32 is equal to the pattern generated by the test pattern generator 54, the memory core 11, the output path 40, the input receiver 31 and the de-serializing circuit 32 probably do not comprise an error, or failure. A method of testing the memory device 10 will be described below in more detail.

FIG. 4 displays a schematic representation of another embodiment of a memory device 10. The memory device 10 displayed in FIG. 4 differs from the memory device 10 described above with reference to FIG. 3 in that an error detection circuit 52 coupled to the output of the input path 30 is provided instead of an error detection circuit 53 coupled to an output of the de-serializing circuit 32. The error detection circuit 52 comprises a test pattern generator 55 configured to generate a test pattern. The error detection circuit 52 can compare the test pattern generated by the test pattern generator 55 with a pattern read from the memory core 11, transmitted via the output path 40, transferred via the degrading device 28, the coupling switch 27 and the coupling device 26 and received via the input path 30. When both compared patterns differ from each other, at least one of the memory core 11, the output path 40 and the input path 30 provides an error, or failure, provided the test pattern generated by the test pattern generator 55 corresponds to the pattern stored in the memory core 11. When both compared patterns are equal to each other, the memory core 11, the output path 40 and the input path 30 most probably do not provide an error, or failure.

In both memory devices 10 described above with reference to the FIGS. 3 and 4, a test pattern generated by the test pattern generator 54 or 55, respectively, can be written to the storage locations 12 of the memory core 11. Therefore, a test of the memory device 10 can be conducted without any support from external circuitry or with very little support from external circuitry. As an alternative, a corresponding test pattern can be provided by external circuitry, received via the input 13 and the input path 30 and written to the storage locations 12 of the memory core 11. Various testing procedures will be described below.

FIG. 5 is a schematic representation of a further embodiment of a memory device 10. The memory device 10 displayed in FIG. 5 differs from the memory devices 10 described above with reference to FIGS. 3 and 4 in that an error detection circuit 51 with a test pattern generator 56 is provided and coupled to the output of the memory core 11. The test pattern generator 56 is provided for and configured to generate a test pattern. The error detection circuit 51 is provided for and configured to compare a pattern received from the output of the memory core 11 with the test pattern generated by the test pattern generator 56. As will be described in more detail below, the pattern received, from the output of the memory core 11, by the error detection circuit 51 is a function of the sequence of addresses provided to the input of the memory core 11. Therefore, when the pattern received, from the output of the memory core 11, by the error detection circuit 51 equals the test pattern generated by the test pattern generator 56, it can be concluded that there is most probably no error in the memory core 11, the output path 40 and the input path 30, provided the test pattern generated by the test pattern generator and the pattern stored in the memory core 11 correspond to each other. When the pattern received, from the output of the memory core 11, by the error detection circuit 51 differs from the test pattern generated by the test pattern generator 56, at least one of the memory core 11, the output path 40 and the input path 30 provides an error, or failure.

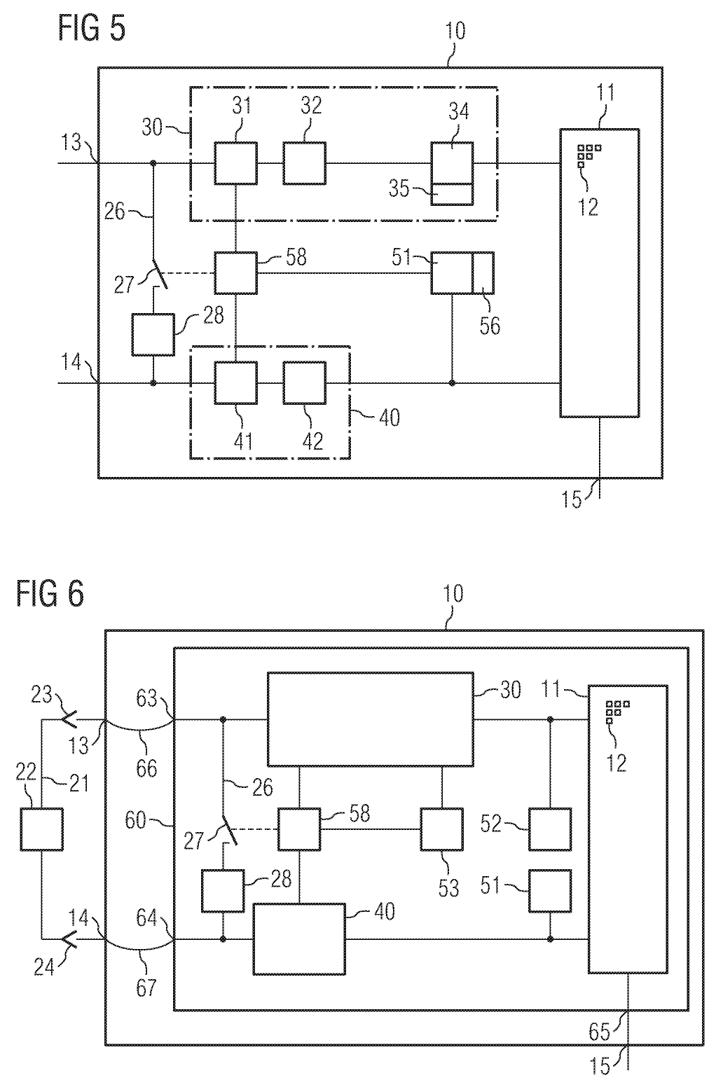

As already mentioned above, each of the memory devices 10 described above with reference to the FIGS. 1 to 5 can be a semiconductor die, or chip, with or without package, or any other memory device. FIG. 6 shows some more details of the memory device 10 comprising a semiconductor die 60 in a package. The semiconductor die 60 comprises the memory core 11 with the storage locations 12, the output path 40, the input path 30, the degrading device 28, the coupling switch 27, the coupling device 26, the test mode controller 58, the error detection circuits 51, 52, and 53 or at least some of these components in a configuration as described above with reference to one of the FIGS. 1 to 5. As an alternative, the components can be distributed over a plurality of semiconductor dies or other substrates. For example, the coupling switch 27 and the optional degrading device 28 can be arranged at a separate substrate.

An input 63 and an output 64 are provided on the semiconductor die 60. For example, each of the input 63 and the output 64 of the semiconductor die 60 comprises a number of bond pads, wherein each of the bond pads is connected to one contact of the input 13 or the output 14, respectively, of the memory device 10 via a bond wire. Each of reference numerals 66 and 67 represents one or several bond wires or other means coupling the input 13 of the memory device 10 to the input 63 of the die 60 and coupling the output 14 of the memory device 10 to the output 64 of the die 60, respectively.

As already described above, the input 13 can be coupled to the output 14 of the memory device 10 by a coupling device 21 optionally comprising a degrading device 22. The coupling device 21 and the degrading device 22 can be part of a testing apparatus provided for and configured to test a memory device 10. As an alternative, the coupling device 26, the coupling switch 27 and the degrading device 28 shown in FIG. 6 are provided as parts of the memory device 10, and also as parts of the semiconductor die 60, similar to the embodiments described above with reference to the FIGS. 1 and 3 to 5.

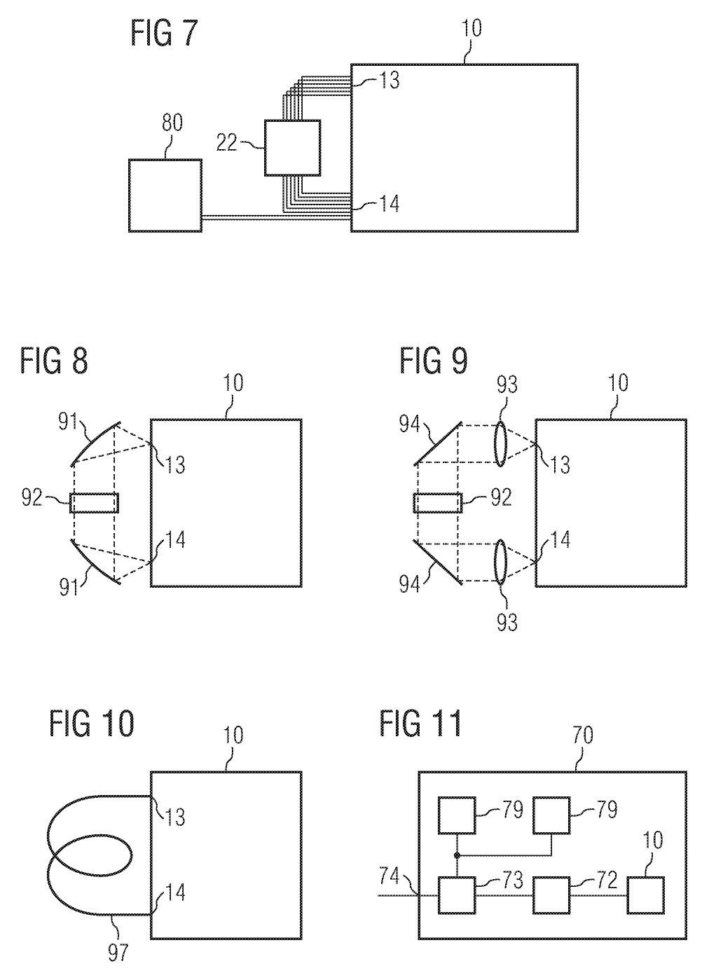

FIG. 7 is a schematic representation of a memory device 10 with an input 13 and an output 14. The memory device 10 displayed in FIG. 7 can provide an internal structure as described above with reference to one of the FIGS. 1 to 6. Contrary to the FIGS. 1 to 6, for both the input 13 and the output 14 a number of signal lines are displayed. The number of signal lines of the input 13 and the number of signal lines of the output 14 can deviate from the schematic representation displayed in FIG. 7. Each of the signal lines of the input 13 is coupled to one of the signal lines of the output 14 via a degrading device 22 as described above with reference to the FIGS. 2 and 6. When the number of signal lines of the output 14 is larger than the number of signal lines of the input 13, those signal lines, of the output 14, not coupled to signal lines of the input 13 can be coupled to an external memory tester 80. As will be described in more detail below, the external memory tester 80 receives a bit pattern from the memory device 10. From this bit pattern, it can be concluded whether the memory device 10 provides an error.

The FIGS. 8 to 10 are schematic representations of memory devices 10 as described above with reference to the FIGS. 1 to 6 but provided with optical inputs 13 and outputs 14. In this case, the external coupling device 21 is replaced by optical devices. The input 13 and the output 14 of the memory devices 10 are coupled to each other via plane, spherical or otherwise curved mirrors, lenses, optical fibers and other optical components.

Referring to FIG. 8, the optical input 13 of the memory device 10 is coupled to the optical output 14 of the memory device 10 by mirrors 91 and an optional degrading device 92. The mirrors 91 provide curved surfaces thereby focusing light emanating from the output 14 to the input 13.

Referring to FIG. 9, the input 13 is coupled to the output 14 via lenses 93, plane mirrors 94 and an optional degrading device 92. The focal lengths of the lenses 93 are selected such and the lenses 93 and the mirrors 94 are arranged such that light emanating from the output 14 is focused to the input 13 of the memory device 10.

Referring to FIG. 10, the input 13 is coupled to the output 14 of the memory device 10 via an optical fiber 97.

As already mentioned in the description of the FIGS. 1 to 9, the degrading devices 22, 28, and 92 are optional. A degrading device 22, 28, or 92 can be provided for and configured to delay or disturb any signal transferred via the internal coupling device 26 or external coupling device 21, to apply noise to the signal or to degrade the signal in another way. As an option, the degradation of the signal can be modified, or adjusted, for example by the test mode controller 58 described above with reference to the FIGS. 1 and 3 to 5 or by the memory tester 80 described above with reference to FIG. 7.

As an alternative, the coupling device as a whole, including an input connector 23, an output connector 24, electrical lines, a coupling switch 27, mirrors 91 or 94, lenses 93 or an optical fiber 97, can degrade the signal transferred from the output 14 to the input 13 of the memory device 10. In any case, the degradation of the signal can simulate the degradation of a signal by any signal path to or from external circuitry in a normal operating mode.

FIG. 11 is a schematic representation of a system 70 comprising a memory device 10 as described above with reference to one of the FIGS. 1 to 6. Further, the system 70 comprises a memory controller 72, a processor 73 and further circuitry 79, for example a chip set, a hard disk drive, an optical drive etc. The system 70 comprises an interface 74 provided for and configured to exchange information with a keyboard, a mouse, a display, a local area network, the world wide web, a bus according to an industry standard etc. The memory device 10 is coupled to the processor 73 via the memory controller 72. The processor 73 is coupled to the interface 74 directly or via circuitry not displayed in FIG. 11. Further circuitry 79 is coupled to the processor 73 directly or via other circuitry or devices.

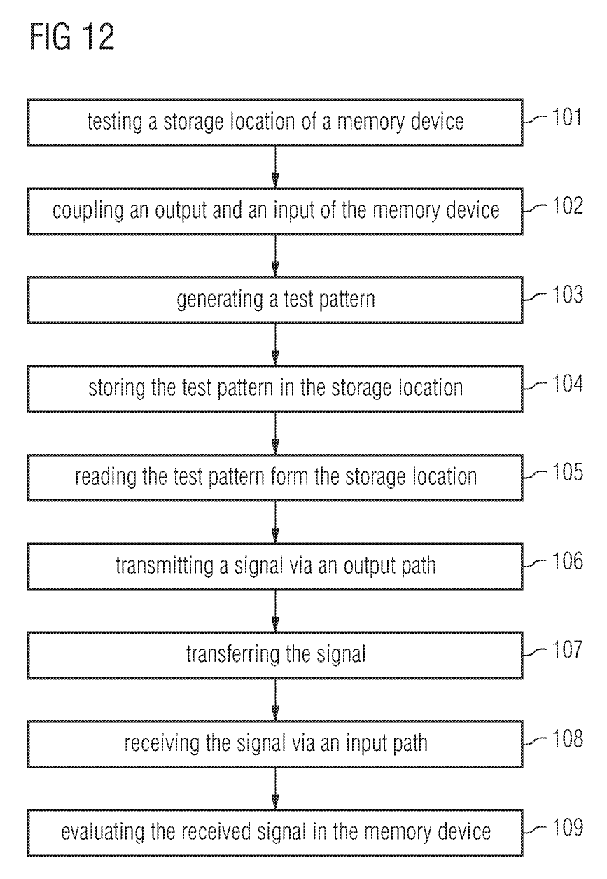

FIG. 12 is a schematic flow chart of a method of testing a memory device 10. This method can, for example, be applied to one of the memory devices 10 described above with reference to the FIGS. 1 to 6. In an exemplary way only, the subsequent description will refer to the embodiments described above and to the reference numerals in the Figures. However, the method can be applied to other memory devices 10 as well.

In a first step 101, the storage location 12 or a plurality of storage locations 12 or all the storage locations 12 of the memory device 10 are tested. With this test, an auxiliary interface 15 can be used, wherein the auxiliary interface 15 can be partly or completely integrated with at least one of the input 13 and the output 14 of the memory device 10. For example, some or all of electrical contacts of the auxiliary interface 15 can be identical with some or all of electrical contacts of the input 13 and the output 14. As an alternative, the auxiliary interface 15 is completely separate from the input 13 and the output 14.

The auxiliary interface 15 may provide a slow and simple access to the storage locations 12 without the use of the output path 40 or the input path 30. The auxiliary interface 15 may be configured for a test mode protocol which is less complex than the protocol used with the input 13 of the memory device 10 in a normal operating mode of the memory device 10. The test mode protocol can be a quite simple protocol, for example a protocol merely allocating or assigning each of a number of simultaneously transferred bits to one of a corresponding number of parallel lines.

As an alternative, at least one of the input 13 and the output 14 of the memory device 10 can be used during the first step 101. In this case no auxiliary interface 15 needs to be provided. A test mode protocol can be used for the first step 101 which is less complex than the protocol used with the input 13 of the memory device 10 in a normal operating mode of the memory device 10. Again, the test mode protocol can be a quite simple protocol, for example a protocol merely allocating or assigning each of a number of simultaneously transferred bits to one of a corresponding number of parallel lines.

The first step 101 may include a replacement of defective storage locations 12 by redundant storage locations 12. Only when it is possible to replace all defective storage locations 12 by redundant storage locations 12, the subsequent steps described below will be conducted.

The first step 101 is optional. The subsequent steps described below can be applied to any memory device 10, the storage locations 12 of which are known to be defect-free. For example, the storage locations 12 of a memory device 10 can be known to be defect-free when they already have been tested in a separate procedure. As an alternative, an error correction circuit corrects errors resulting from defective storage locations 12 which are not replaced by redundant storage locations 12. As a further alternative, the subsequent steps described below are applied to a memory device 10, the storage locations 12 of which are not known to be defect free. In this case, any defect of storage locations 12 will be detected, although not necessarily localized, in the subsequent steps.

In a second step 102, an output 14 and an input 13 of the memory device 10 are coupled to each other. This step can be conducted by means of internal features, for example by means of the coupling device 26, the coupling switch 27 and the optional degrading device 28 described above with reference to the FIGS. 1, 3, 4 and 5. As an alternative, the output 14 and the input 13 of the memory device 10 can be coupled to each other via an external coupling device 21 as described above with reference to FIG. 2. As already mentioned above, the internal coupling device 26 or external coupling device 21 may comprise a dedicated degrading device 22 or 28, respectively. As an alternative, the internal coupling device 26 or external coupling device 21, as a whole, can degrade the signal coupled from the output 14 to the input 13 in one of the above described ways. The second step 102 can comprise at least one of coupling via one or several electrically conductive lines, coupling via one or several optical fibers 97, coupling via one or several light guides, coupling via one or several lenses 93, coupling via one or several mirrors 91 or 94, and coupling via one or several wave guides.

In a third step 103, a test pattern is generated. For example, this test pattern is a pseudo random pattern or any other predefined test pattern generated by a test pattern generator 54, 55, or 56, wherein the test pattern generator 54, 55, or 56 can be an internal member of the memory device 10 or can be external to the memory device 10. When the test pattern is generated external to the memory device 10, the test pattern can, for example, be provided to the memory core 11 of the memory device 10 via the auxiliary interface 15 or via the input 13 and the input path 30 of the memory device 10. When the test pattern is generated within the memory device 10, the test pattern can, for example, be generated by one of the test pattern generators 54, 55, and 56 described above with reference to the FIGS. 3, 4 and 5, respectively. For this purpose, the test pattern generators 54, 55, and 56 are, for example, configured to generate a pseudo random bit sequence.

In a fourth step 104 the test pattern is stored in one or several storage locations 12 out of a plurality of storage locations 12 of the memory device 10.

In a fifth step 105, the test pattern is read from the storage location 12 or from the plurality of storage locations 12. In a sixth step 106, a signal is transmitted via the output 14 of the memory device 10. The test pattern read in the fifth step 105 is encoded in this signal or controls the signal in another way. In a seventh step 107, the signal is transferred from the output 14 of the memory device 10 to the input 13 of the memory device 10. As already described above, this transfer may include a degradation of the signal. In an eighth step 108, the (degraded) signal is received via an input path 30 of the memory device 10. In a ninth step 109, the received signal is evaluated within the memory device 10.

In the embodiments described above with reference to the FIGS. 1 to 3, the ninth step 109 can be conducted by the error detection circuit 53 coupled to the output of the de-serializing circuit 32. In this case, the error detection circuit 53 evaluates the received signal by evaluating the data or information output by the de-serializing circuit 32. In case of the memory device 10 described above with reference to FIG. 3, the error detection circuit 53 compares the data, or information received from the output of the de-serializing circuit 32 with the test pattern generated by the test pattern generator 54.

In case of one of the memory devices 10 described above with reference to FIGS. 1 and 2 comprising an error detection circuit 52 coupled to the output of the input path 30, or in case of the memory device 10 described above with reference to FIG. 4, the error detection circuit 52 evaluates the received signal by evaluating the data, or information provided at the output of the protocol decoder 34. In case of the memory device 10 described above with reference to FIG. 4, the error detection circuit 52 compares this data, or information provided by the output of the protocol decoder 34 with a test pattern generated by the test pattern generator 55.

In the memory devices 10 described above with reference to FIGS. 1, 2 and 5 comprising an error detection circuit 51 coupled to the output of the memory core 11, the error detection circuit 51 evaluates the received signal by evaluating the data, or information, provided at the output of the memory core 11. In case of read commands received by the memory core 11, the data read from storage locations 12 and provided at the output of the memory core 11 are a function of the address received by the memory core 11 via the input path 30. As far as the data stored at different storage locations 12 differ from each other, the data provided at the output of the memory core 11 can be used to conclude which address was provided to the input of the memory core 11. In the case of the memory device 10 described above with reference to FIG. 5, the error detection circuit 51 compares the data, or information, received from the output of the memory core 11 with the test pattern generated by the test pattern generator 56.

In all the memory devices 10 described above with reference to the FIGS. 1 to 5, the fifth step 105, the sixth step 106, the seventh step 107, the eighth step 108 and the ninth step 109 can be repeated several times. For example, the test pattern stored in the storage locations 12 of the memory core 11 is configured such that each data provided at the output of the memory core 11 comprises a read command. As long as this read command is not corrupted by the output path 40, the coupling device 26 or the coupling device 21, respectively, and the input path 30, a plurality of cycles of reading (fifth step 105), transmitting (sixth step 106), transferring (seventh step 107) and receiving (eighth step 108) are conducted. When there is no error, or failure, in the memory core 11, the output path 40 and the input path 30, a predefined sequence of data will be read from the memory core 11 by a predefined sequence of read commands comprising a predefined sequence of addresses of storage locations 12 provided to the memory core 11.

The error detection circuit 51 coupled to the output of the memory core 11 can monitor the data provided at the output of the memory core 11, for example by comparing the data with the pattern generated by the test pattern generator 56 described above with reference to FIG. 5 wherein the pattern generator 56 generates a predefined sequence of data. As an alternative, the error detection circuit 53, described above with reference to FIG. 3, coupled to the output of the de-serializing circuit 32 or the error detection circuit 52, described above with reference to FIG. 4, coupled to the output of the input path 30 evaluates the commands provided to the memory core 11. For example, the error detection circuit 53 or the error detection circuit 52, respectively, compares the sequence of commands provided to the input of the memory core 11 with the predefined sequence of commands generated by the pattern generator 54 or 55, respectively.

Monitoring, or comparing, all the bits of data in all cycles can, under certain conditions, provide a very high coverage and can facilitate that the point of time of the occurrence of almost any potential error, or failure of the memory device 10 can be detected. Thereby, monitoring all bits in all cycles can facilitate the detection and even the localization of errors. As an alternative, only one or few bits in each cycle are monitored. As a further alternative, only predefined cycles are monitored, for example only every n^{th} command or data. As a further alternative, only one command or data after a predefined number of cycles is evaluated. In the last two cases, the error detection circuit 51, 52 or 53 or the test mode controller 58 or any other internal or external circuitry counts the cycles and starts an evaluation of the present data or command, respectively after the predefined number of cycles.

As a further alternative, only a predefined command is evaluated. For example, the pattern stored in the memory core 11 is such that a predefined number of cycles are conducted, wherein in each of the predefined number of cycles a read command is provided to the memory core 11, and wherein a predefined command different from the read command and identifying the end of the predefined number of cycles occurs after the predefined number of cycles. The error detection circuit 51, 52 or 53 identifies this predefined command and checks whether this command provides predefined details or whether the predefined command occurred after the predefined number of cycles.

As a variant of all the embodiments described above, the test mode controller 58, after storing 104 the test pattern in the storage locations 12, starts the first reading 105 from a predefined storage location 12. The pattern stored in the storage locations 12 of the memory core 11 is such that a predefined number (including one) of cycles is conducted, each cycle comprising the fifth step 105, the sixth step 106, the seventh step 107 and the eighth step 108. The ninth step 109 may be conducted in each cycle or at the occurrence of a predefined data, or command, or after a predefined number of cycles. As an alternative, the test mode controller 58 controls the third step 103 of generating a test pattern and the fourth step 104 of storing the test pattern in the storage locations 12, too, in particular when the test pattern is generated within the memory device 10, for example by one of the test pattern generators 54, 55, and 56.

As a further alternative the posted write buffer 35 of the protocol decoder 34 can be used for the storage of a control pattern. This control pattern is stored in the posted write buffer 35 with a normal or a slightly modified posted write command or with a dedicated command. The protocol decoder 34 can be configured to compare each and every command, address or data information received from the de-serializer 32 with the control pattern stored in the posted write buffer 35, wherein any occurrence of the control pattern at the input of the protocol decoder 34 is notified to the test mode controller 58 or to other internal or external circuitry. As a further alternative, the protocol decoder 34 is coupled to the test mode controller 58 and is configured to compare, controlled by the test mode controller 58, any command provided to the input of the protocol decoder 34 with the control pattern stored in the posted write buffer 35. In any case, the test mode controller 58 can be integrated with the protocol decoder 34.

In case of the memory device 10 described above with reference to FIG. 7, the external memory tester 80 can be configured to monitor the testing procedure by monitoring those signal lines of the output 14 of memory device 10 which are not coupled to the input 13 of the memory device 10. By monitoring these lines, the external memory tester 18 can detect an error, or failure, of the memory device 10.

As a further variant of all the embodiments described above, the test mode controller 58 can, before or during the test of the memory device 10, tune or adjust detection thresholds, phase offsets, voltage offsets or other parameters of the input receiver 31 or other components of the input path 30 or phase offsets, amplitudes, voltage offsets or other parameters of the output driver 41 or other components of the output path 40. Tuning these parameters can facilitate a test of the set points of the parameters or of the robustness of the entire configurations of the output path 40 and the input path 30.

According to one embodiment, the communication of a memory device 10 via the input 13 and the output 14 is based on frames. Each frame provided at the output 14 of the memory device 10 comprises a predefined number of bits, or channels, in parallel and a sequence of a predefined number of bits at each channel, and each frame received at the input of the memory device 10 comprises a predefined number of bits, or channels in parallel and a sequence of a predefined number of bits at each channel. For example, each frame comprises eight bits, or channels in parallel, transmitted via at least eight parallel lines, and eighteen bits in serial in each channel. In this example, each frame received at the input of the memory device 10 comprises eight bits, or channels, in parallel to be received via at least eight parallel lines, and a sequence of nine bits at each channel. As a consequence, each frame transmitted from the output of the output path 40 of the memory device 10 will be interpreted as two frames in the input path 30 of the memory device 10.

As an alternative, the beginning of each frame or the end of each frame or the border between each pair of two consecutive frames is identified by a predefined pattern which is not allowed to appear within a frame. In this case, the length of each frame is variable.

In case of predefined lengths of the frames, the length of each frame provided at the output 14 of the memory device 10 can be a predefined integer multiple of the length of each frame received at the input 13 of the memory device 10. For example, each of the above-described cycles comprises the transmission of one frame (of eighteen bits per channel) at the output path 40 and the reception of two frames (of nine bits per channel) at the input path 30 of the memory device 10. As long as one of the frames received in one cycle comprises a read command, data will be read from the memory core 11 again and again. For some protocols, it might be helpful to avoid any situation in which both frames received in one cycle comprise a read command. As long as these two conditions are fulfilled, one frame received in each cycle can comprise any command, for example a NOP (No Operation), ACT, BRCH or any other command which is no read command and which is not in conflict with the read command in the other frame received in the same cycle.

The non-read command or commands in each cycle can be called payload of the respective cycle. For example, this payload can be used to monitor the testing procedure by one of the error detection circuits 51, 52, and 53 or the external memory tester 80. In some embodiments, the payload can also be used to load a new compare pattern into the posted write buffer 35 or into one of the error detection circuits 51, 52, and 53.

It has been described that the data read in each cycle from the memory core 11 comprise one read command controlling the next cycle and implicitly determining which data will be read from the memory core 11 in the next cycle. As an alternative, in the test mode, a predefined number of storage locations 12 are read in sequence. For example, an interval of consecutive addresses is called by the test mode controller 58 or by circuitry within the memory core 11 or by any other circuitry within the memory device 10, wherein the addresses are simply incremented by one or any other predefined value in each cycle. A test pattern is stored at the storage locations 12 identified by these addresses. The error detection circuit 52 coupled to the output of the input path 30 or the error detection circuit 53 coupled to the output of the de-serializing circuit 32 monitors what arrives after transmission by the output path 40, transfer via the degrading device 28, the coupling switch 27 and the coupling device 26 or the degrading device 22 and the coupling device 21 and reception by the input path 30. For this purpose, each of the error detection circuits 52, 53, and 54 has built-in algorithm providing the same pattern that is stored at the predefined sequence of addresses in the memory core 11.

As a further alternative, a pseudo random address sequence is provided to the input of the memory core 11. This pseudo random address sequences for example generated by the test mode controller 58 or test mode circuitry within the memory core 11 or by any other circuitry within the memory device 10. At the storage locations 12 identified by the addresses of the pseudo random address sequence, a predefined sequence of data is stored. Monitoring these predefined sequences of data can be simplified by the provision of only a small number of different data, for example four different data.

The above described method and its variants can include the transmission and reception of an error correction code, for example in accordance with a cyclic redundancy check. The production of an error correction code can be integrated in the output path 40, and the detection of the error correction code can be integrated in the input path 30. Thereby, the production and the detection of an error detection code can be tested with the above-described method, too.

All or some of the above-described steps can be conducted before or after cutting or cleaving a wafer comprising a large number of dies and before or after packaging of the single dies. For example, the first step 101 is conducted before a die is cut out of the wafer or before the die is packaged. Some of the above-described steps can be conducted in a sequence different from the sequence displayed in FIG. 12 and described above. For example, the second step 102 can be conducted after the fourth step 104 of storing the test pattern and before the fifth step of reading the test pattern. The third step 103 of generating the test pattern and the fourth step 104 of storing the test pattern can be conducted immediately before or a long time before the fifth step 105 of reading the test pattern. The second step 102 of coupling the input 13 and the output 14 to each other can be conducted any time before sixth step 106 of transmitting a signal, for example before the fifth step 105 of reading the test pattern. If the fifth to eighth steps 105 to 108, and optionally the ninth step 109, are repeated a number of times, the input 13 and the output 14 of the memory device 10 can be coupled to each other as long as these steps are repeated.

Some of the embodiments described above comprise a protocol decoder 34, explicitly or implicitly refer to a protocol decoder 34, or refer to the decoding of a protocol. The protocol decoder 34 may provide a specific advantage, at least under certain conditions. However, it is to be noted that the protocol decoder 34 can be omitted in each of the embodiments and many of their variants described above or not described above. The invention may also be applied to memory devices 10 without a protocol decoder 34.

The preceding description describes advantageous exemplary embodiments. The features disclosed therein and the claims and the drawings can, therefore, be useful for realizing various embodiments, both individually and in any combination. While the foregoing is directed to specific embodiments, other and further embodiments may be devised without departing from the basic scope, the scope being determined by the claims that follow.

1. A method of testing a memory device, the method comprising:
coupling an output of the memory device and an input of the memory device;
transmitting a signal via the output of the memory device, wherein the signal is controlled by a test pattern;
receiving the signal via the input of the memory device; and
evaluating the received signal.

2. The method of claim 1, wherein the received signal is evaluated within the memory device.

3. The method of claim 1, further comprising:
reading the test pattern from a storage location in the memory device;

4. The method of claim 3, further comprising:
storing the test pattern in the storage location of the memory device.

5. The method of claim 1, further comprising:
testing the storage location.

6. The method of claim 5, wherein
the step of transmitting includes transmitting the signals with a first data rate via the output of the memory device, and
the step of testing the storage location includes transferring, with a second data rate, information via at least one of the input, the output, and an interface, wherein the interface is different from the input and the output of the memory device.

7. The method of claim 6, wherein the second data rate is lower than the first data rate.

8. The method of claim 6, wherein
the step of transmitting includes transmitting the signals according to a first protocol via the output of the memory device,
the step of testing the storage location includes transferring, according to a second protocol, information via at least one of the input, the output, and the interface, and
the second protocol is different from the first protocol.

9. The method of claim 5, wherein the step of testing the storage location comprises:
generating, in the memory device, the test pattern.

10. The method of claim 1, wherein the step of coupling comprises coupling the output and the input via a coupling device external to the memory device.

11. The method of claim 10, wherein the external coupling device comprises at least one of an electrically conductive line, an optical fiber, a wave guide, a lens, and a mirror.

12. The method of claim 1, wherein
the step of coupling comprises coupling the output and the input via a coupling device, and
the coupling device performs at least one of degrading, delaying, perturbing and applying noise to the signal transferred via the coupling device.

13. The method of claim 1, wherein the step of coupling comprises coupling the output and the input via a coupling device integrated with the memory device.

14. The method of claim 1, wherein the step of evaluating comprises evaluating the received signal within the memory device.

15. The method of claim 1, wherein a data output of the memory device is coupled to an address input of the memory device.

16. An apparatus for testing a memory device, the apparatus comprising:
an output configured to couple with an input of a memory device;
an input configured to couple with an output of the memory device; and
a coupling device coupled with the input and output, wherein, while testing the memory device, the coupling device is configured to receive a signal from the memory device via the input, degrade the signal while preserving all information carried by the signal, and transmit the degraded signal back to the memory device via the output.

17. The apparatus of claim 16, wherein the coupling device is further configured to at least one of delay, perturb and apply noise to the signal received from the memory device.

18. The apparatus of claim 16, wherein the apparatus further comprises a test pattern generator configured to generate a test pattern, wherein the test pattern controls the signal transmitted to the output, and wherein the signal comprises, encodes, or represents data, an address, and control information.

19. An integrated circuit having a memory device, the memory device comprising:
a storage location for storing information;
an output for transmitting a signal from the memory device to circuitry external to the memory device;
an input for receiving the signal from circuitry external to the memory device; and
at least one of a plurality of error detection circuits configured to evaluate information encoded in the signal received via the input.

20. The integrated circuit of claim 19, further comprising:
an internal coupling device for switchably connecting the output and the input of the memory device.

21. The integrated circuit of claim 20, wherein the internal coupling device comprises a degrading device, and wherein the degrading device is configured for at least one of degrading, delaying, perturbing and applying noise to a signal transferred via the internal coupling device.

22. The integrated circuit of claim 19, further comprising a test pattern generator configured to generate a test pattern, wherein the test pattern controls the signal transmitted via the output of the memory device, and wherein the signal comprises at least one of:
(i) data, an address, or control information;
(ii) encoded data, an encoded address, or encoded control information; and
(iii) a representation of data, an address, or control information.

23. The integrated circuit of claim 22, wherein the test pattern generator is coupled to the storage location, and wherein the memory device is configured to write, in a test mode, the test pattern generated by the test pattern generator and stored in the storage location.

24. The integrated circuit of claim 19, wherein an input of the error detection circuit is coupled to at least one of an input of the storage location and an output of the storage location.

25. The integrated circuit of claim 19, further comprising an interface different from the input and different from the output, wherein
the output and the input are configured for a frame-based communication at a first data rate,
the interface is configured for a communication at a second data rate, and the second data rate is lower than the first data rate.

26. The integrated circuit of claim 19, further comprising an interface different from the input and different from the output, wherein
the output and the input are configured for a communication according to a first protocol,
the interface is configured for a communication according to a second protocol, and
the second protocol is different from the first protocol.

27. The integrated circuit of claim 19, wherein the memory device is configured for being tested by a method, comprising:
coupling the output of the memory device and the input of the memory device;
transmitting a signal via the output of the memory device, wherein the signal is controlled by a test pattern;
receiving the signal via the input of the memory device; and
evaluating the received signal.

28. An integrated circuit having a memory device, the memory device comprising:
a storage location for storing information;
an output for transmitting a signal from the memory device to circuitry external to the memory device;
an input for receiving the signal from circuitry external to the memory device; and
an internal coupling device switchably connecting the output and the input of the memory device.

29. The integrated circuit of claim 28, wherein the memory device is configured for performing a method, comprising:
coupling the output of the memory device and the input of the memory device;
transmitting a signal via the output of the memory device, wherein the signal is controlled by a test pattern;
receiving the signal via the input of the memory device; and
evaluating the received signal.

30. A system comprising an integrated circuit of a memory device, wherein the integrated circuit comprises:
a storage location for storing information;
an output for transmitting a signal from the memory device to circuitry external to the memory device;
an input for receiving the signal from the circuitry external to the memory device; and
at least one of a plurality of error detection circuits configured to evaluate information encoded in the signal received via the input.

31. The system of claim 30, wherein the system is a computer system comprising a central processing unit.

32. The system of claim 31, the system further comprising:
a memory controller coupled to the memory device.

33. The apparatus of claim 16, further comprising at least one of a plurality of error detection circuits for evaluating the signal received from the memory device.
